(19) United States
(12) Patent Application Publication
(10) Pub. No.: US 2014/0116494 A1
(43) Pub. Date: May 1, 2014

(54) High-Efficiency Four-Junction Solar Cells and Fabrication Methods Thereof

(71) Applicant: XIAMEN SANAN OPTOELECTRONICS TECHNOLOGY CO., LTD., Xiamen (CN)

(72) Inventors: ZHIHAO WU, Xiamen (CN); GUIJIANG LIN, Xiamen (CN); MINGHUI SONG, Xiamen (CN); YANYAN FANG, Xiamen (CN); JIANGNAN DAI, Xiamen (CN); CHANGQING CHEN, Xiamen (CN); JINZHONG YU, Xiamen (CN); ZHIDONG LIN, Xiamen (CN)

(73) Assignee: XIAMEN SANAN OPTOELECTRONICS TECHNOLOGY CO., LTD., Xiamen (CN)

(21) Appl. No.: 14/147,596

(22) Filed: Jan. 6, 2014

Related U.S. Application Data
(63) Continuation of application No. PCT/CN2012/078233, filed on Jul. 5, 2012.

(30) Foreign Application Priority Data
Aug. 2, 2011 (CN) 201110219051.X

(51) Int. Cl. H01L 31/0725; H01L 31/18

(52) U.S. Cl. CPC H01L 31/0725; H01L 31/1844
USPC 136/244; 136/255; 438/74

(57) ABSTRACT

A high-efficiency four-junction solar cell includes: an InP growth substrate; a first subcell formed over the growth substrate, with a first band gap, and a lattice constant matched with that of the growth substrate; a second subcell formed over the first subcell, with a second band gap larger than the first band gap, and a lattice constant matched with that of the growth substrate; a third subcell formed over the second subcell, with a third band gap larger than the second band gap, and a lattice constant matched with that of the substrate lattice; a composition gradient layer formed over the third subcell, with a fourth band gap larger than the third band gap; and a fourth subcell formed over the composition gradient layer, with a fifth band gap larger than the third band gap, and a lattice constant mismatched with that of the substrate.

### CROSS-REFERENCE TO RELATED APPLICATIONS

The present application claims priority to PCT Application No. PCT/CN2012/078233, filed on Jul. 5, 2012 and published on Jan. 10, 2013 as publication No. WO 2013/004188 A1, which claims priority to Chinese Patent Application No. 201110219051.X, filed on Aug. 2, 2011, entitled “High-Efficiency Four-Junction Solar Cells and Fabrication Methods Thereof.” The disclosures of these applications are incorporated herein by reference in their entirety.

### BACKGROUND

In recent years, with the development of concentrating photovoltaic technologies (CPV), more attentions are being paid to III-V compound semiconductor solar cells due to their high photoelectric conversion efficiency. A clean energy system such as a solar farm may comprise a plurality of solar panels each having multiple solar cells.

### SUMMARY

The present disclosure relates to epitaxial growth of compound semiconductor solar cells and more specifically to structures and fabrication methods of four-junction solar cells.

In an aspect, a high-efficiency four-junction solar cell is provided including: an InP growth substrate; a first subcell formed over the growth substrate, wherein the first subcell has a first band gap, and a lattice constant matched with that of the growth substrate; a second subcell formed over the first subcell, wherein the second subcell has a second band gap larger than the first band gap, and a lattice constant matched with that of the growth substrate; a third subcell formed over the second subcell, wherein the third subcell has a third band gap larger than the second band gap and a lattice constant matched with that of the substrate lattice; a composition gradient layer formed over the third subcell, wherein the composition gradient layer has a fourth band gap larger than the third band gap; and a fourth subcell formed over the composition gradient layer, wherein the fourth subcell has a fifth band gap larger than the third band gap, and a lattice constant mismatched with that of the substrate.

In some embodiments, the first subcell includes an InGaAs emitter layer and a base layer; the second subcell includes an InₓGa₁₋ₓAs_{y}P_{1-y} emitter layer and a base layer; the values of x and y ensure that the lattice constant of the InₓGa₁₋ₓAs_{y}P_{1-y} is the same as that of the substrate; the third subcell includes an InP emitter layer and a base layer; and the fourth subcell comprises an InGaP emitter layer and a base layer.

In some embodiments, the first subcell has a band gap from about 0.72 eV to about 0.76 eV; the second subcell has a band gap from about 0.9 eV to about 1.1 eV; the third subcell has a band gap of about 1.31 eV; and the fourth subcell has a band gap from about 1.8 eV to about 2.0 eV.

In some embodiments, the composition gradient layer, through variation of a composition ratio, matches with the lattice of the growth substrate at one side and with the lattice of the fourth subcell at the other side.

In some embodiments, the composition gradient layer includes an AlSb_{z}As_{1-z}, layer and the composition ratio is gradually varied from AlSb_{0.44}As_{0.56} to AlAs.

In another aspect, a method of fabricating a high-efficiency four-junction solar cell is provided, the method including: providing an InP growth substrate; forming a first subcell over the growth substrate, wherein the first subcell has a first band gap, and a lattice constant matched with that of the substrate; forming a second subcell over the first subcell, wherein the second subcell has a second band gap larger than the first band gap, and a lattice constant matched with that of the growth substrate; forming a third subcell over the second subcell, wherein the third subcell has a third band gap larger than the second band gap and a lattice constant matched with that of the substrate lattice; forming a composition gradient layer over the third subcell, wherein the composition gradient layer has a fourth band gap larger than the third band gap; and forming a fourth subcell over the composition gradient layer, wherein the fourth subcell has a fifth band gap larger than the third band gap, and a lattice constant mismatched with that of the substrate.

In some embodiments, the first subcell includes an InGaAs emitter layer and a base layer; the second subcell includes an InₓGa₁₋ₓAs_{y}P_{1-y} emitter layer and a base layer; the values of x and y ensure that the lattice constant of the InₓGa₁₋ₓAs_{y}P_{1-y} is the same as that of the substrate; the third subcell includes an InP emitter layer and a base layer; and the fourth subcell includes an InGaP emitter layer and a base layer.

In some embodiments, the first subcell has a band gap from about 0.72 eV to about 0.76 eV; the second subcell has a band gap from about 0.9 eV to about 1.1 eV; the third subcell has a band gap of about 1.31 eV; and the fourth subcell has a band gap from about 1.8 eV to about 2.0 eV.

In some embodiments, the composition gradient layer, through variation of a composition ratio, matches with the lattice of the growth substrate at one side and with the lattice of the fourth subcell at the other side.

In some embodiments, the composition gradient layer includes an AlSb_{z}As_{1-z}, layer and the composition ratio is gradually varied from AlSb_{0.44}As_{0.56} to AlAs.

In some embodiments, the method further includes cleaning InP growth substrate at 9 degrees of deflection angle to the (001) surface; and disposing the growth substrate in a metal-organic chemical vapor deposition (MOCVD) reaction chamber.

In some embodiments, the method further includes baking the growth substrate at about 750° C. for about 10 minutes.

In some embodiments, the method further includes selecting a carrier gas of hydrogen; selecting In, Ga, and Al sources of TMIn, TMG, TMA organic metal sources; and selecting P, As, and Sb sources of PH3, AsH3, SbH3.

In some embodiments, said forming a first subcell includes: lowering a temperature in the MOCVD chamber to about 600° C.; and growing a p-type InGaAsP back surface field layer.

In some embodiments, said forming a first subcell further includes: growing a p-type In_{0.53}Ga_{0.47}As base region with a doping concentration of about 1×10¹⁷ cm⁻³ and a thickness about 3 μm; growing an n-type In_{0.53}Ga_{0.47}As emitter layer with a doping concentration of about 2×10¹⁸ cm⁻³ and a thickness about 100 nm; and growing an n-type InP window layer 104 with a doping concentration of about 1×10¹⁸ cm⁻³ and a thickness about 50 nm.

In another aspect, a system is provided including a plurality of high-efficiency four-junction solar cells, wherein each solar cell includes: an InP growth substrate; a first subcell formed over the growth substrate, wherein the first subcell has a first band gap, and a lattice constant matched with that of the growth substrate; a second subcell formed over the first subcell, wherein the second subcell has a second band gap larger than the first band gap, and a lattice constant matched with that of the growth substrate; a third subcell formed over the second subcell, wherein the third subcell has a third band gap larger than the second band gap and a lattice constant matched with that of the substrate lattice; a composition gradient layer formed over the third subcell, wherein the composition gradient layer has a fourth band gap larger than the third band gap; and a fourth subcell formed over the composition gradient layer, wherein the fourth subcell has a fifth band gap larger than the third band gap, and a lattice constant mismatched with that of the substrate.

In some embodiments, the first subcell includes an InGaAs emitter layer and a base layer; the second subcell includes an InₓGa₁₋ₓAs_{y}P_{1-y} emitter layer and a base layer; the values of x and y ensure that the lattice constant of the InₓGa₁₋ₓAs_{y}P_{1-y} is the same as that of the substrate; the third subcell includes an InP emitter layer and a base layer; and the fourth subcell includes an InGaP emitter layer and a base layer.

In some embodiments, the first subcell has a band gap from about 0.72 eV to about 0.76 eV; the second subcell has a band gap from about 0.9 eV to about 1.1 eV; the third subcell has a band gap of about 1.31 eV; and the fourth subcell has a band gap from about 1.8 eV to about 2.0 eV.

In some embodiments, the composition gradient layer, through variation of a composition ratio, matches with the lattice of the growth substrate at one side and with the lattice of the fourth subcell at the other side.

In some embodiments, the first subcell further includes a p-type InGaAsP back surface field layer, and an n-type InP window layer; the second subcell further includes a p-type InP back surface field layer, and an n-type InP window layer; the third subcell further includes a p-type AlInAs back surface field layer, and an n-type AlInAs window layer; the fourth subcell further includes a p-type AlInP back surface field layer, and an n-type AlInP window layer; each solar cell further includes: a first tunnel junction comprising a series of n++-In_{0.53}Ga_{0.47}As/p++-In_{0.53}Ga_{0.47}As for coupling the first subcell with the second subcell; a second tunnel junction comprising a series of n++-InGaAsP/p++-InGaAsP coupling the second subcell with the third subcell 300; a third tunnel junction comprising a series of n++-AlInAs/p++-AlInAs for coupling the third subcell with the fourth subcell; the composition gradient layer includes an AlSb_{z}As_{1-z}, layer and the composition ratio is gradually varied from AlSb_{0.44}As_{0.56} to AlAs, and wherein the Sb composition variation rate is about 8%/μm.

At least one of the disclosed embodiments may have advantages as compared with existing technologies of forming an InGaP/GaAs/InGaNAs/Ge four-junction solar cell on the Ge substrate or forming a four-junction inverted metamorphic multi junction solar cell with two metamorphic layers on a GaAs substrate.

For example, a four-junction solar cell according to some of the disclosed embodiments may now be formed on an InP substrate adopting a forward-direction growth structure for the convenience of element preparation; the band gaps of subcells may be arranged more suitably and the lattices of three subcells at the bottom portion may be completely matched with the substrate; the threading dislocation density of the InGaP subcell on the top portion may be controlled within 10⁶ cm⁻² by the composition gradient AlSb_{z}As_{1-z}, thus minimizing the efficiency loss of the subcell.

### BRIEF DESCRIPTION OF THE DRAWINGS

FIG. 1 is a side cross-sectional view of a high-efficiency four-junction solar cell according to some embodiments.

### DETAILED DESCRIPTION

The details of the disclosure, including the demonstrations and embodiments, will be described below with reference to the diagrams and texts. Same reference numbers may denote elements of same or similar functions, and the highly-simplified drawings are used to illustrate the main characteristics of the example embodiments.

Charts illustrating band gaps and lattice constants of some binary materials may be found, for example, in E. F. Shubert, Light-emitting diodes, 2nd ed., Cambridge University Press, 2006; or from P. K. Tien of AT&T Bell Laboratories (1988), the disclosures of which are hereby incorporated by reference in their entirety. The band gaps and lattice constants of the ternary materials can be found on the lines prepared between typical and related binary materials. For example, ternary material AlGaAs, in the curve chart, is between the point GaAs and the point AlAs, wherein, the bank gap of the ternary material is between 1.42 eV of GaAs and 2.16 eV of AlAs subject to the relative amount of individual composition. Therefore, the ternary material of suitable material composition may be selected subject to the required band gap for growth.

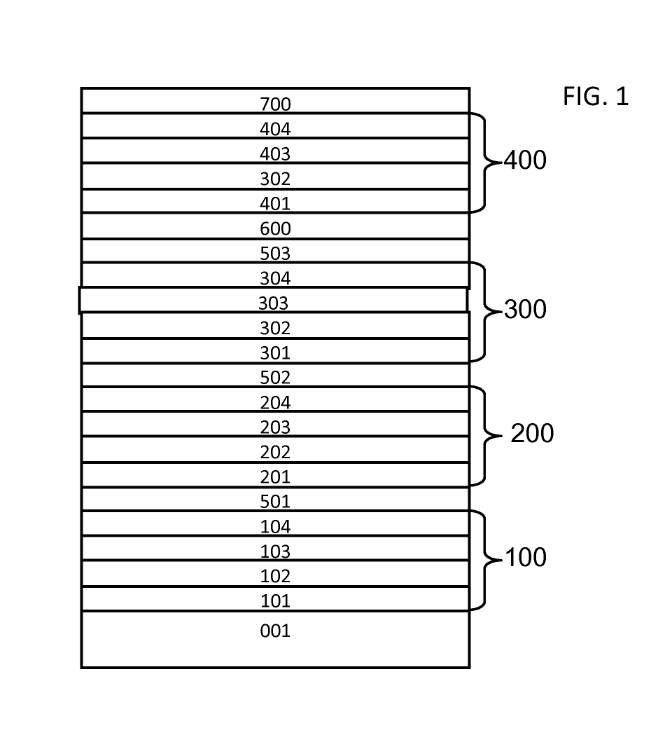

Referring to FIG. 1, a high-efficient four-junction solar cell comprises an InP growth substrate 001, a first subcell 100, a second subcell 200, a third subcell 300, and a fourth subcell 400, wherein, the subcells of each junction are coupled with tunnel junctions 501, 502, and 503.

The first subcell 100 can have a band gap of about 0.74 eV, and may be formed over and lattice-matched with the growth substrate 001. The first subcell comprises a back surface field layer 101, a base region 102, an emitter layer 103, and a window layer 104. More specifically, the growth substrate 001 can be p-type InP, the base region 102 of the first subcell 100 can be p-type In_{0.53}Ga_{0.47}As, the emitter layer 103 of the first subcell 100 can be n-type In_{0.53}Ga_{0.47}As, and the window layer 104 can be n-type InP. The material of the back surface field layer 101 can be p-type InGaAsP, wherein the composition ratio of the InGaAsP allows its lattice constant to be matched with the substrate, and that the band gap is about 0.9 eV-1.1 eV.

A series of n++-In_{0.53}Ga_{0.47}As/p++-In_{0.53}Ga_{0.47}As can be deposited over the n-type Inp window layer 104 on a top portion of the first subcell 100, to form the tunnel junction 501 for coupling the first subcell 100 with the second subcell 200.

The second subcell 200 can have a band gap of about 1.0 eV, and may be formed over the tunnel junction 501 and lattice-matched with the growth substrate. The second subcell may comprise a back surface field layer 201, a base region 202, an emitter layer 203, and a window layer 204. More specifically, the back surface field layer 201 can be p-type InP; the base region 202 can be p-type InₓGa₁₋ₓAs_{y}P_{1-y}; the emitter layer 203 can be n-type InₓGa₁₋ₓAs_{y}P_{1-y}; and the window layer 204 can be n-type InP. The values of x and y can ensure that the lattice constant of the InₓGa₁₋ₓAs_{y}P_{1-y} is the same as that of the substrate, and that the band gap is about 1.0 eV.

A series of n++-InGaAsP/p++-InGaAsP can be deposited over the n-type InP window layer 204 over the top portion of the second subcell 200, to form the tunnel junction 502 for coupling the second subcell 200 with the third subcell 300. The composition ratio of the InGaAsP can ensure that its lattice constant is matched with that of the substrate, and that the band gap is about 1.0 eV.

The third subcell 300 can have a band gap of about 1.31 eV, and can be lattice-matched with the growth substrate and formed over the tunnel junction 502. The third subcell may comprise a back surface field layer 301, a base region 302, an emitter layer 303, and a window layer 304. More specifically, the back surface field layer 301 can be p-type AlInAs; the base region 302 can be p-type InP; the emitter layer 303 can be n-type InP; and the window layer 304 can be n-type AlInAs. The composition ratio of AlInAs back surface field layer 301 can ensure that its lattice constant is matched with that of the substrate, and that the band gap may be about 1.47 eV. The Al composition can be preferably about 0.48, and the In composition may be 0.52. The composition ratio of the window layer can be the same as that of the back surface field layer 301.

A series of n++-AlInAs/p++-AlInAs can be deposited over the window layer 304 on the top portion of the third subcell 300, to form the tunnel junction 503 for coupling the third subcell 300 with the fourth subcell 400. The composition ratio of this layer can be the same as that of the back surface field layer 301.

A gradient layer 600, having a band gap larger than that of the third subcell 300, can be formed over the tunnel junction 503. More specifically, the gradient layer 600 can comprise p-type AlSb_{z}As_{1-z}. The composition ratio can be gradually variation from AlSb_{0.44}As_{0.56} with a band gap of about 1.9 eV, which is lattice matched with the InP substrate, to AlAs. The gradual variation can comprise a stepped variation, a linear variation, etc.

The fourth subcell 400, having a band gap of about 1.88 eV, can be formed over the composition gradient layer 600. The fourth subcell may comprise a back surface field layer 401, a base region 402, an emitter layer 403, and a window layer 404. More specifically, the back surface field layer 401 can comprise p-type AlInP; the base region 402 can comprise p-type InGaP; the emitter layer 403 can comprise n-type InGaP; and the window layer 404 can comprise n-type AlInP.

A GaAs contact layer 700 can cover the window layer 401 in the top portion of the fourth subcell as the cap layer, to form the high-efficiency four-junction solar cell.

Different from the existing technologies of forming an InGaP/GaAs/InGaNAs/Ge four-junction solar cell on Ge substrate and forming a four-junction inverted metamorphic multi-junction solar cell of two metamorphic layers on GaAs substrate, the present disclosure realizes a four-junction solar cell on InP substrate. A forward-direction growth structure may be adopted and is beneficial for the device preparation. The band gaps of the subcells may be arranged suitably and the lattices of three bottom subcells may be completely matched with that of the substrate. In addition, the threading dislocation density of the InGaP subcell in the top portion can be controlled to be within 10⁶ cm⁻² through AlSb_{z}As_{1-z} with gradually varying compositions, thus minimizing the efficiency loss of the subcell.

Methods of manufacturing the high-concentration multi junction solar cells described above may comprise the formation processes of subcell 100, subcell 200, subcell 300, subcell 400, and the layers among the subcells. The lattice constants and electrical properties in the semiconductor structure can be controlled by appropriate chemical compositions and doping agents under suitable growth temperature and within suitable growth time. The growth technology can be vapor deposition methods such MOCVD and MBE. Preferably MOCVD is adopted according to some embodiments.

Detailed preparation techniques may comprise the following steps:

In a first step, an InP growth substrate 001 may be provided. The InP substrate at 9 degrees of deflection angle to the (001) surface may be cleaned, and the substrate may be disposed into a metal-organic chemical vapor deposition reaction chamber. The substrate may be baked it at about 750° C. for about 10 minutes. The carrier gas can be hydrogen; the In, Ga, and Al sources can be TMIn, TMG, TMA organic metal sources; and the P, As and Sb sources can be PH3, AsH3, SbH3.

In the next step, the first subcell 100, having a band gap of about 0.74 eV and lattice-matched with the substrate, can be formed through epitaxial growth over the p-type InP substrate 001 using MOCVD. More specifically, the temperature may be lowered to about 600° C., and the p-type InGaAsP back surface field layer 101 may be first grown. The composition ratio of the

InGaAsP can ensure that the lattice constant is matched with that of the substrate; the band gap can be from about 0.9 eV to about 1.1 eV, and the thickness can be about 20 nm; the p-type In_{0.53}Ga_{0.47}As base region 102 can be grown next, with a doping concentration of about 1×10¹⁷ cm⁻³ and a thickness about 3 μm; next, an n-type In_{0.53}Ga_{0.47}As emitter layer 104 can be grown, with a doping concentration of about 2×10¹⁸ cm⁻³ and a thickness about 100 nm; and lastly, the n-type InP window layer 104 can be grown, with a doping concentration of about 1×10¹⁸ cm⁻³ and a thickness about 50 nm.

In the next step, the tunnel junction 501 may be grown over the n-type InGaAsP window layer 104 on the top portion of the first subcell 100. The n-type In_{0.53}Ga_{0.47}As layer with a thickness about 15 nm and a doping concentration of about 1×10¹⁹ cm⁻³ can be grown first, followed by the p-type In_{0.53}Ga_{0.47}As layer with a thickness about 15 nm and a doping concentration of about 1×10¹⁹ cm⁻³.

In the next step, the second subcell 200, having a band gap of about 1.0 eV and lattice-matched with the substrate, may be formed through epitaxial growth over the tunnel junction 501. The p-type InP back surface field layer 201 with a thickness of about 20 nm can be grown first; then the p-type InGaAs base region 202 can be grown, with a doping concentration of about 1×10¹⁷ cm⁻³ and a thickness of about 3 μm; the n-type InGaAs emitter layer 203 can then be grown, with a doping concentration of about 2×10¹⁸ cm⁻³ and a thickness of about 100 nm; the composition ratios of the two layers can ensure that the lattice constant matches with that of the substrate, with a band gap of about 1.0 eV; the n-type InP window layer 204 can be grown next, with a doping concentration of about 1×10¹⁸ cm⁻³ and a thickness of about 50 nm.

In the next step, the tunnel junction 502 may be grown over the n-type InP window layer 204 on the top portion of the second subcell 200. The composition ratios of the two layers can ensure that the lattice constant matches with with the substrate, with a band gap of about 1.0 eV. The n-type InGaAsP layer can be grown, with a thickness of 15 nm and a doping concentration of about 1×10¹⁹ cm⁻³, followed by the growth of the p-type InGaAsP layer with a thickness of about 15 nm and a doping concentration of about 1×10¹⁹ cm⁻³.

In the next step, the third subcell 300, having a band gap of about 1.31 eV and lattice-matched with the substrate, can be formed through epitaxial growth over the tunnel junction 502.

The p-type AlInAs back surface field layer 301 with a thickness of about 20 nm may be grown first, and the composition ratio of the AlInAs back surface field layer 301 can ensure that the lattice constant matches that of the substrate, with a band gap of about 1.47 eV. Preferably, 0.48 for the Al composition and 0.52 for the In composition are selected. Next, the p-type InP base region 302 with a thickness of about 1 μm may be grown, having a doping concentration of about 1×10¹⁷ cm⁻³; the n-type InP emitter layer 303 with a thickness of about 100 nm and a doping concentration of about 2×10¹⁸ cm⁻³ may be grown next; followed by the growth of the n-type AlInAs window layer 304 with a thickness of about 50 nm and a doping concentration of about 1×10¹⁸ cm⁻³, wherein, the composition ratio of the layer can be same as that of the back surface field layer 301.

In the next step, tunnel junction 503 can be grown over the n-type AlInAs window layer 304 on the top portion of the third subcell 300; an n-type AlInAs layer with a thickness of about 15 nm and a doping concentration of about 1×10¹⁹ cm⁻³ may be grown first; followed by a p-type AlInAs layer with a thickness of about 15 nm and a doping concentration of about 1×10¹⁹ cm⁻³, wherein the composition ratio of the layer may be same as that of the back surface field layer 301.

In the next step, a composition gradient layer 600 may be formed through epitaxial growth over the tunnel junction 503. A p-type AlSbxAs1−x gradient layer 600 can be grown, to ensure that the composition ratio is gradually varied, from AlSb_{0.44}As_{0.56} with a band gap of about 1.9 eV and lattice-matched with the InP substrate, to AlAs. The variation can comprise a stepped variation, a linear variation, etc. The Sb composition variation rate can be about 8%/μm. In the case of step variation, every 250 nm grown is a step.

In the next step, the fourth subcell 400 with a band gap of about 1.88 eV may be grown through epitaxial growth over the composition gradient layer 600. A p-type AlInP back surface field layer 401 with a thickness of about 20 nm and a doping concentration of about 2×10¹⁸ cm⁻³ may be grown first; followed by the growth of a p-type InGaP base 402 with a thickness of about 500 nm and a doping concentration of about 1×10¹⁷ cm⁻³; next, an n-type InGaP emitter layer 403 with a thickness of about 100 nm and a doping concentration of about 2×10¹⁸ cm⁻³ may be grown; at last, an n-type AlInP window layer 404 with a thickness of about 50 nm and a doping concentration of about 1×10¹⁸ cm⁻³ may be grown.

In the next step, an n-type GaAs contact layer 700 of heavy doping may be formed over the n-type AlInP window layer 404 on the top portion of the fourth subcell 400 through epitaxial growth, thus completing the growth of the four-junction solar cell structure.

All references are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A high-efficiency four-junction solar cell, comprising:
an InP growth substrate;
a first subcell formed over the growth substrate, wherein the first subcell has a first band gap, and a lattice constant matched with that of the growth substrate;
a second subcell formed over the first subcell, wherein the second subcell has a second band gap larger than the first band gap, and a lattice constant matched with that of the growth substrate;
a third subcell formed over the second subcell, wherein the third subcell has a third band gap larger than the second band gap and a lattice constant matched with that of the substrate lattice;
a composition gradient layer formed over the third subcell, wherein the composition gradient layer has a fourth band gap larger than the third band gap; and
a fourth subcell formed over the composition gradient layer, wherein the fourth subcell has a fifth band gap larger than the third band gap, and a lattice constant mismatched with that of the substrate.

2. The solar cell according to claim 1, wherein:
the first subcell comprises an InGaAs emitter layer and a base layer;
the second subcell comprises an InₓGa₁₋ₓAs_{y}P_{1-y} emitter layer and a base layer;
the values of x and y ensure that the lattice constant of the InₓGa₁₋ₓAs_{y}P_{1-y} is the same as that of the substrate;
the third subcell comprises an InP emitter layer and a base layer; and
the fourth subcell comprises an InGaP emitter layer and a base layer.

3. The solar cell according to claim 1, wherein:
the first subcell has a band gap from about 0.72 eV to about 0.76 eV;
the second subcell has a band gap from about 0.9 eV to about 1.1 eV;
the third subcell has a band gap of about 1.31 eV; and
the fourth subcell has a band gap from about 1.8 eV to about 2.0 eV.

4. The solar cell according to claim 1, wherein the composition gradient layer, through variation of a composition ratio, matches with the lattice of the growth substrate at one side and with the lattice of the fourth subcell at the other side.

5. The solar cell according to claim 1, wherein the composition gradient layer comprises an AlSb_{z}As_{1-z}, layer and the composition ratio is gradually varied from AlSb_{0.44}As_{0.56} to AlAs.

6. A method of fabricating a high-efficiency four-junction solar cell, the method comprising:
providing an InP growth substrate;
forming a first subcell over the growth substrate, wherein the first subcell has a first band gap, and a lattice constant matched with that of the substrate;
forming a second subcell over the first subcell, wherein the second subcell has a second band gap larger than the first band gap, and a lattice constant matched with that of the growth substrate;
forming a third subcell over the second subcell, wherein the third subcell has a third band gap larger than the second band gap and a lattice constant matched with that of the substrate lattice;
forming a composition gradient layer over the third subcell, wherein the composition gradient layer has a fourth band gap larger than the third band gap; and
forming a fourth subcell over the composition gradient layer, wherein the fourth subcell has a fifth band gap larger than the third band gap, and a lattice constant mismatched with that of the substrate.

7. The method of claim 6, wherein:
the first subcell comprises an InGaAs emitter layer and a base layer;
the second subcell comprises an InₓGa₁₋ₓAs_{y}P_{1-y} emitter layer and a base layer;
the values of x and y ensure that the lattice constant of the InₓGa₁₋ₓAs_{y}P_{1-y} is the same as that of the substrate;
the third subcell comprises an InP emitter layer and a base layer; and
the fourth subcell comprises an InGaP emitter layer and a base layer.

8. The method of claim 6, wherein:
the first subcell has a band gap from about 0.72 eV to about 0.76 eV;
the second subcell has a band gap from about 0.9 eV to about 1.1 eV;
the third subcell has a band gap of about 1.31 eV; and
the fourth subcell has a band gap from about 1.8 eV to about 2.0 eV.

9. The method of claim 6, wherein the composition gradient layer, through variation of a composition ratio, matches with the lattice of the growth substrate at one side and with the lattice of the fourth subcell at the other side.

10. The method of claim 6, wherein the composition gradient layer comprises an AlSb_{z}As_{1-z}, layer and the composition ratio is gradually varied from AlSb_{0.44}As_{0.56} to AlAs.

11. The method of claim 6, further comprising:
cleaning InP growth substrate at 9 degrees of deflection angle to the (001) surface; and
disposing the growth substrate in a metal-organic chemical vapor deposition (MOCVD) reaction chamber.

12. The method of claim 11, further comprising baking the growth substrate at about 750° C. for about 10 minutes.

13. The method of claim 12, further comprising:
selecting a carrier gas of hydrogen;
selecting In, Ga, and Al sources of TMIn, TMG, TMA organic metal sources; and
selecting P, As, and Sb sources of PH3, AsH3, SbH3.

14. The method of claim 12, wherein said forming a first subcell comprises:
lowering a temperature in the MOCVD chamber to about 600° C.; and
growing a p-type InGaAsP back surface field layer.

15. The method of claim 14, wherein said forming a first subcell further comprises:
growing a p-type In_{0.53}Ga_{0.47}As base region with a doping concentration of about 1×10¹⁷ cm⁻³ and a thickness about 3 μm;
growing an n-type In_{0.53}Ga_{0.47}As emitter layer with a doping concentration of about 2×10¹⁸ cm⁻³ and a thickness about 100 nm; and
growing an n-type InP window layer 104 with a doping concentration of about 1×10¹⁸ cm⁻³ and a thickness about 50 nm.

16. A system comprising a plurality of high-efficiency four-junction solar cells, wherein each solar cell comprises:
an InP growth substrate;
a first subcell formed over the growth substrate, wherein the first subcell has a first band gap, and a lattice constant matched with that of the growth substrate;
a second subcell formed over the first subcell, wherein the second subcell has a second band gap larger than the first band gap, and a lattice constant matched with that of the growth substrate;
a third subcell formed over the second subcell, wherein the third subcell has a third band gap larger than the second band gap and a lattice constant matched with that of the substrate lattice;
a composition gradient layer formed over the third subcell, wherein the composition gradient layer has a fourth band gap larger than the third band gap; and
a fourth subcell formed over the composition gradient layer, wherein the fourth subcell has a fifth band gap larger than the third band gap, and a lattice constant mismatched with that of the substrate.

17. The system of claim 16, wherein:
the first subcell comprises an InGaAs emitter layer and a base layer;
the second subcell comprises an InₓGa₁₋ₓAs_{y}P_{1-y} emitter layer and a base layer;
the values of x and y ensure that the lattice constant of the InₓGa₁₋ₓAs_{y}P_{1-y} is the same as that of the substrate;
the third subcell comprises an InP emitter layer and a base layer; and
the fourth subcell comprises an InGaP emitter layer and a base layer.

18. The system of claim 17, wherein:
the first subcell has a band gap from about 0.72 eV to about 0.76 eV;
the second subcell has a band gap from about 0.9 eV to about 1.1 eV;
the third subcell has a band gap of about 1.31 eV; and
the fourth subcell has a band gap from about 1.8 eV to about 2.0 eV.

19. The system of claim 18, wherein the composition gradient layer, through variation of a composition ratio, matches with the lattice of the growth substrate at one side and with the lattice of the fourth subcell at the other side.

20. The system of claim 19, wherein:
the first subcell further comprises a p-type InGaAsP back surface field layer, and an n-type InP window layer;
the second subcell further comprises a p-type InP back surface field layer, and an n-type InP window layer;
the third subcell further comprises a p-type AlInAs back surface field layer, and an n-type AlInAs window layer;
the fourth subcell further comprises a p-type AlInP back surface field layer, and an n-type AlInP window layer;
each solar cell further comprises:
a first tunnel junction comprising a series of n++-In_{0.53}Ga_{0.47}As/p++-In_{0.53}Ga_{0.47}As for coupling the first subcell with the second subcell;
a second tunnel junction comprising a series of n++-InGaAsP/p++-InGaAsP coupling the second subcell with the third subcell 300;
a third tunnel junction comprising a series of n++-AlInAs/p++-AlInAs for coupling the third subcell with the fourth subcell; and
the composition gradient layer comprises an AlSb_{z}As_{1-z}, layer and the composition ratio is gradually varied from AlSb_{0.44}As_{0.56} to AlAs, and
wherein the Sb composition variation rate is about 8%/μm.
